(19) United States
(12) Patent Application Publication
(10) Pub. No.: US 2009/0047417 A1
(43) Pub. Date: Feb. 19, 2009

(54) METHOD AND SYSTEM FOR VAPOR PHASE APPLICATION OF LUBRICANT IN DISK MEDIA MANUFACTURING PROCESS

(76) Inventors: Michael S. Barnes, San Ramon, CA (US); Charles Liu, Los Altos, CA (US); Ren Xu, San Jose, CA (US)

Correspondence Address: NIXON PEABODY, LLP, 401 9TH STREET, NW, SUITE 900, WASHINGTON, DC, 20004-2128, US

(21) Appl. No.: 12/060,174

(22) Filed: Mar. 31, 2008

Related U.S. Application Data
(60) Provisional application No. 60/909,162, filed on Mar. 30, 2007.

(51) Int. Cl. C23C 14/54; B05C 11/10; B05D 5/12

(52) U.S. Cl. 427/9; 118/696; 427/127

(57) ABSTRACT

Lubricant coatings are applied as vapor to magnetic disks. The method and apparatus include applying vaporizing heat to a pre-determined amount of liquid to form a vapor. Precision delivery of lubricant vapor allows close-loop lube thickness control. The flow of the liquid to the heater is controlled such that only a pre-determined amount from the reservoir flows to the heater at a time, the pre-determined amount is vaporized. According to an aspect, the pre-determined amount of liquid is transferred from the reservoir for the application of vaporizing heat; isolating the reservoir from the vacuum of the vacuum chamber. The method enables multiple types of lubricants to be applied to the disk. Another heater is included for applying vaporizing heat to a second liquid to form a second vapor to supply to the disk. According to an aspect, pulsed lubricant vapor delivery is provided, conserving lubricant and minimizing thermal decomposition.

### RELATED APPLICATIONS

This Application claims priority from U.S. Provisional Patent Application Ser. No. 60/909,162, filed on Mar. 30, 2007, the disclosure of which is incorporated herein in its entirety.

### FIELD OF THE INVENTION

The present invention relates generally to applying lubricant vapor to a media to form a lubricant coating on a media, and more particularly, to a method and apparatus for vapor phase application of a pre-measured amount of lubricant to a disk surface in a disk manufacturing process

### BACKGROUND

In the art of hard disk fabrication, it is known to apply lubricants to the disks during fabrication. Known methods utilize vacuum vapor lube chamber designs that are integrated or connected to a stand-alone tool utilizing one or two vacuum vapor lube chambers. More specifically, in the prior art, method and apparatus are known for coating hard magnetic disks with a lubricant film by applying the lubricant, e.g., a perfluoropolyether (PFPE), in gaseous vapor form to a magnetic layer on the disks in a vacuum vapor lube chamber. The magnetic disks are sequentially loaded into a flow path of the vapor by a carrying blade that lifts the disks out of cassettes transported into and out of the vacuum vapor lube chamber. The lubricant is placed in an especially designed reservoir and evaporated therein at vacuum utilizing elevated temperature. The resulting vapor flows via a vapor volume through an apertured diffuser plate prior to being deposited on a surface of the disk. The diffuser plates, one for each side of the disk, are mounted on the outside of the vacuum vapor lube chamber, also referred to herein as a vaporization chamber. The diffuser plates are included for controlling the uniformity of the lubricant spatial distribution.

Generally, the vapor lube chamber includes a shutter to control the start and stop of the vapor deposition onto the disk surface for thickness control and uniformity. Within each vaporization chamber, a single type of lubricant is stored in the heated reservoir. The single type of lubricant is continuously heated in the reservoir to generate lubricant vapor. The lubricant vapor is allowed to diffuse to the surface of a disk through the shuttered diffuser plate.

According to some implementations, a single quartz crystal microbalance (QCM) is included in a gauge for monitoring the flow rate of the lubricant vapor being evaporated from the liquid lubricant source. Along with the monitoring, a feedback loop is provided to control the amount of heat applied to the liquid lubricant source and thereby control the temperature of the liquid lubricant and the mass flow rate of vapor lubricant evaporated from the liquid lubricant source. The build-up of lube thickness on the crystal is proportional to the amount of lubricant deposited on the disk. For further information the reader is directed to commonly-assigned U.S. Pat. No. 6,183,831 to Hughes, et al., and to U.S. Pat. No. 5,776,577.

FIG. 1 is a top view of a portion of a prior art vapor source 10, having a multi-head QCM 12; shuttered QCM exposure 14, a shuttered diffuser 16, a large lube reservoir 18, and dual heating zones 20. Improvements introduced by the device of FIG. 1 include maintaining surfaces of a vapor volume at different temperatures to prevent substantial lubricant vapor condensation on one of the surfaces; providing a selectively opened and closed shutter (i.e., shuttered diffuser 16) in the flow for the vapor such that the amount of liquid lubricant that is consumed during idle periods is minimized even though heat is continuously applied to the liquid lubricant during the idle periods; and including plural crystal based monitors (i.e., multi-head QCM 12) for detecting the flow rate of lubricant vapor to increase the lifetimes of the piezoelectric crystals, and also compensating for temperature variations of the crystals by a feedback arrangement for maintaining constant crystal temperature to help maintain monitoring accuracy, (i.e., arrangement including shuttered QCM exposure 14). For further information the reader is directed to commonly-assigned pending patent application Ser. Nos. 11/693,030, 11/693,039, and 11/693,424, which are incorporated by reference herein.

The foregoing arrangements have performed satisfactorily, but can be improved. These known methods have several drawbacks for the lubrication process in the disk manufacturing operations. One drawback of these known methods and apparatus is that only one single type of lubricant is vaporized in each chamber, thereby eliminating potential use of the tool for a disk design where it is desired to have a multiple lubricant type system, also referred to herein as mixed-type lubricant system. Due to complications of different volatilities resulting in different partial vapor pressure for multiple lubricant types when heated, only one lubricant is placed in the heated reservoir used for the known methods. This limits use of the known methods to disk lubricating systems that involves only one molecular type of lubricant.

Another drawback of the known methods is that the mechanical shuttered diffusion of the vapor is not quantitatively measured in each dosage delivery. As a result, the disk-surface lubricant thickness is known only after a post-process measurement is performed. Thus, the control of lubricant thickness is not a closed-loop type of control for the known methods.

Another drawback of the known methods is that the lubricant is heated continuously throughout its lifetime in the reservoir. The continuous heating of all the lubricant in the reservoir causes progressive increase of molecular weight for the remaining lubricant. Due to the increase, a higher reservoir temperature is needed to keep relatively constant vapor pressure. This effect is due to molecular weight distribution and the natural distillation effect. A further drawback due to the continuous heating is that, towards the end of the lubricant quantity remaining, thermal decomposition may result to some fractionation of the lubricant, causing adverse effect of disk surface contamination and reservoir contamination.

Yet another drawback of the known methods is that, upon depletion of the lubricant in the reservoir, venting of the chamber to re-fill is inevitable, causing machine down time and other maintenance inconveniences. Still another drawback of the known methods and apparatus is that condensation of the vaporized lubricant on the chamber wall and other lower temperature surfaces is continuous, even when the shutter is in off cycle.

Yet another drawback of the known methods is that the lubricant is subject to constant evaporation as long as the reservoir is heated, which is continuous until the lubricant in reservoirs is exhausted. This mode of lubricant dispensing is wasteful, as the timing of evaporation is not specific to the disk presence. It is desirable to have a means of dispensing lubricant only when a disk is present in the process chamber.

### SUMMARY

The following summary of the invention is provided in order to assist in basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Broadly stated, embodiments of the present invention provide an apparatus for applying lubricant coatings to magnetic disks selectively held in place on a holder in a vacuum chamber, while vapor that can form the lubricant coatings is applied to one of the disks while the disc is held in place on the holder, the apparatus comprising a reservoir for a liquid; a heater for heating at least a portion of the liquid to a vapor; a controller to control flow of the liquid to the heater such that only a pre-determined amount of the liquid from the reservoir flows to the heater at a time, the heater heating the pre-determined amount to the vapor; and an apertured diffuser in the vacuum chamber, the vapor to flow to the disk through the apertured diffuser.

Broadly stated, embodiments of the present invention also provide a method for applying lubricant coatings to a disk, the method comprising loading a disk on a holder in a vacuum chamber; measuring a pre-determined amount of liquid; applying vaporizing heat to the pre-determined amount of liquid to form a vapor; and supplying the vapor to the disk via a flow path that includes an apertured diffuser. In accordance with one aspect of the invention, a Direct Liquid Injection (DLI) method is provided which utilizes a mass flow controller wherein a calibrated amount of liquid is delivered directly into the vacuum environment, followed with vaporization and subsequent delivery to the process chamber in measured molar quantities.

One of the advantages provided by the present invention is the precision delivery of lubricant vapor which allows close-loop lube thickness control during the lubrication process.

Another advantage provided by the present invention is enabling mixed-lube system disks to be made in the vapor lube process.

Another advantage provided by the present invention is enabling continuous liquid feed into the vaporization source, minimizing down time for lubrication replenishment.

Yet another advantage provided by the present invention is pulsed lubricant vapor delivery which allows conservation of costly lubricant in process and minimizing thermal decomposition which causes contamination.

Yet another advantage provided by the present invention is pulsed lubricant vapor delivery where the precision of delivery is governed by the length and duty cycle of pulses, where vapor flow can be modulated to 100%. This is vastly better than the actuation of a shutter plate, where the flow of vapor cannot be shuttered to better than 70% of total flow.

The above and still further objects, features, aspects, and advantages of the present invention will become better understood with reference to the following description, appended claims and accompanying drawings.

### BRIEF DESCRIPTION OF THE DRAWINGS

FIG. 1 is a top view of a prior art apparatus including a vapor source in combination with a schematic showing a chamber holding a hard magnetic disk to be coated;

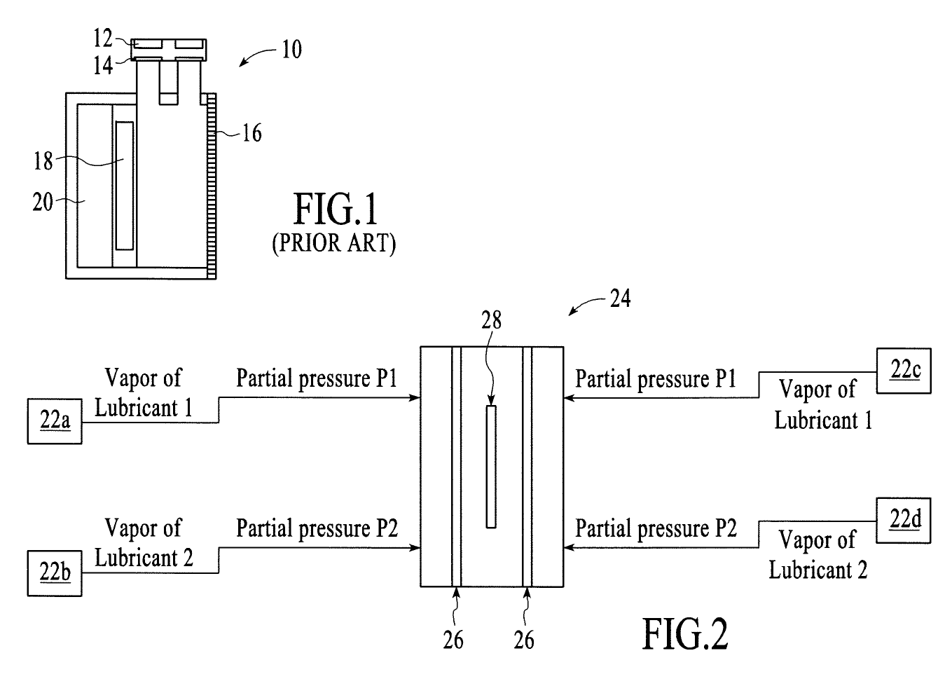

FIG. 2 is a drawing illustrating delivering vapor to the deposition chamber separately from a separate source for each of two types of lubricants, according to an embodiment of the present invention;

FIG. 3a is a drawing illustrating an aspect for delivery of vapor into the deposition chamber in measured quantities, according to an embodiment of the present invention;

FIG. 3b illustrates schematically inclusion of flow control and feedback aspects, according to certain embodiments of the present invention;

FIG. 4 illustrates exemplary timing diagrams for delivery of measured micro-moles of lubricant for heating, vaporization, and subsequent delivery in the vapor phase to the deposition chamber, according to an embodiment of the present invention; and,

FIGS. 5A and 5B are diagrams illustrating isolation of the deposition chamber vacuum from the reservoir of lubricant liquid for enabling replenishment of lubricant liquid without disrupting vacuum operations, according to embodiments of the present invention.

### DETAILED DESCRIPTION

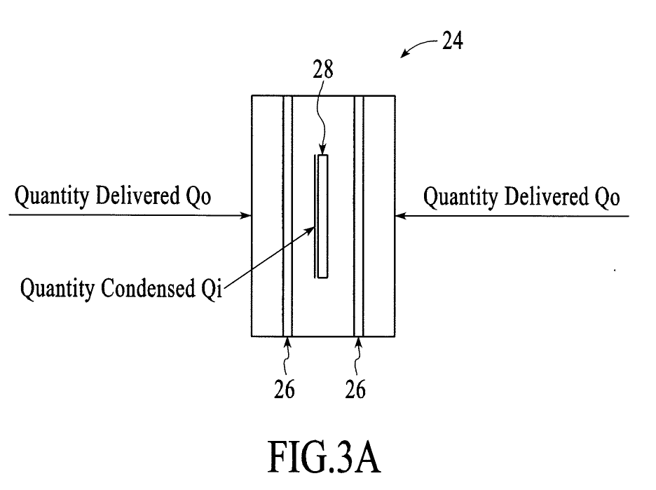

FIG. 2 is a diagram of a subsystem 20 illustrating enabling mixed-lube system disks to be made in the vapor lube process, according to an embodiment of the present invention. As described above, one of the drawbacks of known methods and apparatus is having only one single lubricant vaporized in each chamber, thereby eliminating potential use for a disk design where a mixed-lubricant system is desired. According to an embodiment of the present invention illustrated in the example in FIG. 2, each type of lubricant is subjected to heating and vaporization independently by separate corresponding heating sources. For example, types of perfluoropolyether (PFPE) lubricants, disclosed in U.S. Pat. No. 5,776,577, may be used. In the example in FIG. 2, vapor of a first lubricant (identified in FIG. 2 as “lubricant 1”) from heater 22a at a partial pressure P1 is delivered to the vacuum environment of deposition chamber 24. Vapor of a second lubricant (identified in FIG. 2 as “lubricant 2”) from heater 22b at a partial pressure P2 is delivered to the deposition chamber 24. The resulting vapor flows through an apertured diffuser plate 26 prior to being deposited on a surface of the disk. An apertured diffuser plate 26 is included in deposition chamber 24 on either side of a disk 28 to be lubricated in the deposition chamber 24. Vapor is delivered separately into the vacuum environment of deposition chamber 24 where disk-surface condensation occurs indiscriminately to form a mixed-lubricant film. Corresponding heaters 22c and 22d are arranged for forming vapor to flow through an apertured diffuser plate 26 prior to being deposited on the opposite surface of the disk.

According to another embodiment of the invention, two types of lubricant of a pre-determined proportion are mixed prior to being placed in the liquid reservoir. The mixture is then delivered in precision amount to the evaporator, and co-evaporated to be delivered as vapor through the diffuser plate to the deposition chamber. The condensation of the two types of lubricant on disk surface will then occur in the deposition chamber, resulting at a desired ratio on the disk's surface.

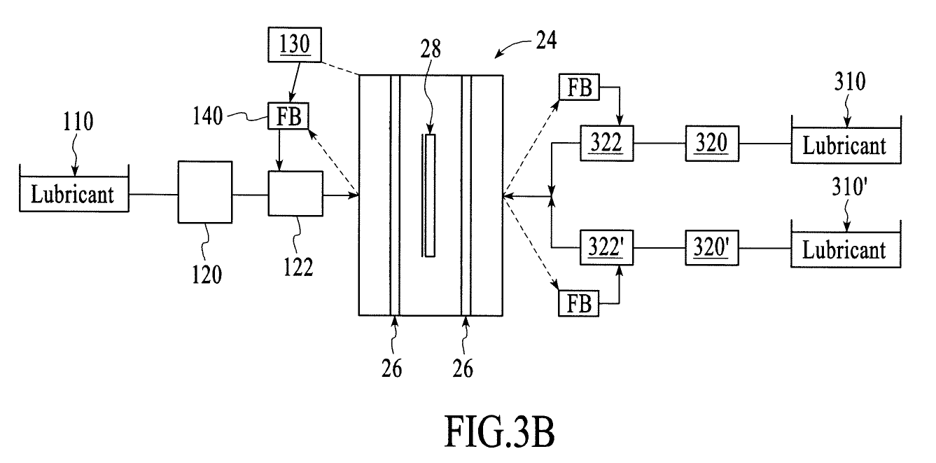

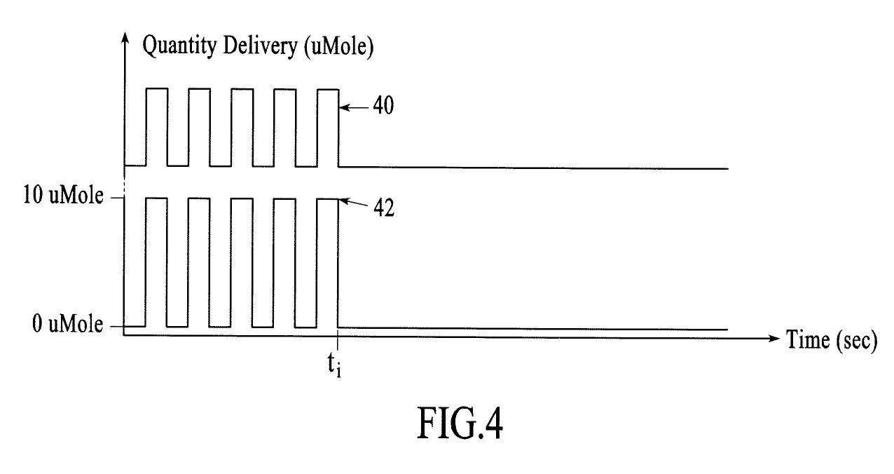

FIG. 3a is a drawing illustrating delivery of vapor into the deposition chamber in measured quantities. A known quantity of liquid lubricant is pre-measured and subsequently subjected to vaporization and total evaporation, shown as quantity delivered Qo. The quantity Qo is delivered to the deposition chamber 24 wherein a quantity flows through the diffuser plate 26 and is condensed onto the disk 28. The quantity condensed is shown at Qi. As illustrated in FIG. 3a, the quantity Qo is delivered on each side of the chamber 24 for each of the two side surfaces of the disk 28 with the quantity condensed thereon of Qi. The deposition efficiency for each side is, therefore, Qi/Qo.

FIG. 3b illustrates schematically inclusion of flow control and feedback aspects according to certain embodiments of the present invention. FIG. 3b illustrates an asymmetrical system, in that the left-hand side is different from the right hand side. As can be understood, this will not be a normal implementation of the invention, but is done rather only to illustrate two differ rent implementations. That is, if the illustration of the left-hand side is selected, it will be mirrored to the right hand side as well, and vice versa. The description first proceeds with respect to the left-hand side example.

A controller 120 in FIG. 3b is included for control to cause only a pre-determined amount of liquid lubricant from the liquid reservoir 110 to flow to a heater 122 for vaporization and subsequent delivery to the deposition chamber 24 as quantity Qo. The controller 120 May be, e.g., a mass flow controller included between a liquid lubricant reservoir 110 and a heater 122, i.e., vaporizer. The inlet of the flow controller may be in ambient, while the outlet in vacuum. In this and other embodiments of the invention, reservoir 110 may include a single tank having a predetermined mixture of liquid mixed therein, or a plurality of tanks, each having a single type of liquid, which is then mixed upon the flow controlled by the controller 120.

According to an embodiment of the present invention, a further calibration is included in addition to the precision delivery in FIG. 3b to establish a correlation between quantity delivered and quantity condensed on the disk-surface as an aid in establishing a close-loop control over the resulting thickness of lubricant. A monitor is included for monitoring the quantity condensed Qi. The monitor 130 is shown schematically in FIG. 3b. According to one embodiment, the monitor includes one or more single quartz crystal microbalances (QCMs) as described in Hughes and pending patent application Ser. Nos. 11/693,030, 11/693,039, and 11/693,424, in a gauge for monitoring the flow rate of the lubricant vapor being evaporated from the liquid lubricant source. The amount of lubricant liquid deposited on the disk is a function of the monitored flow. A feedback controller FB 140 is provided to control the amount of heat applied to the liquid lubricant source as a function of the quantity of lubricant liquid condensed on the disk and the quantity of vapor delivered to the deposition chamber to provide closed-loop thickness control. Thus, measured quantities of vapor is delivered into the deposition chamber 24, and a correlation is made between the quantity of vapor delivered and the quantity of the lubricant liquid condensed on the surface of disk 28. Depending on the correlation, the quantity of vapor delivered into the deposition chamber 24 is adjusted to enable close-loop control over the resulting thickness of the lubricant deposited on the surface of disk 28. It should be appreciated that a corresponding arrangement (not shown) including a reservoir, controller, and monitors may be included for precision vapor deposition on the opposite surface of disk 28. Since the vapor delivery is done in pulses, the pulse duration and duty cycle may be controlled according to the feedback so as to enable highly accurate control of the delivered liquid.

Turning to the example of the right-hand side of FIG. 3b, in this example two different liquids are delivered in separate delivery paths. That is, while in the example of the left-hand side of FIG. 3b several types of liquids may be mixed in the reservoir 110, but delivered together in the same delivery path, in the example of the right-hand side, at least one liquid specie is delivered in a separate flow path. Each of reservoirs 310 and 310′ may contain one or more liquid species therein. Controllers 320 and 320′ control the pulse delivery of the liquid to heaters 322 and 322′ respectively. The vapors from both paths are then mixed in the diffuser so as to be delivered to the disk in a mixed fashion. Feedback, FB, may be utilized to control the deliver from each flow path independently.

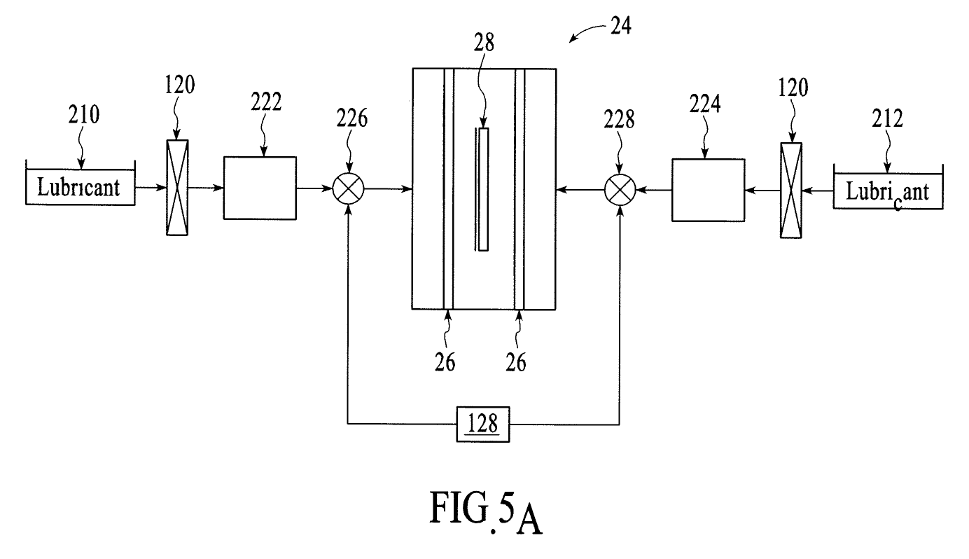

FIG. 4 illustrates exemplary timing diagrams for the delivery of pre-determined measured micro-moles of lubricant for heating, vaporization, and subsequent delivery in the vapor phase to the deposition chamber according to an embodiment of the present invention. According to this embodiment, the method includes heating only sufficient quantities of lubricant to form the desired thickness of the lubricant on the disk surface in each deposition for every disk. Lubricant is delivered in pulsed micro-moles to the heating location, the micro-moles being of sufficient quantity to form the desired thickness. The micro-moles are vaporized by the heating, and subsequently delivered in the vapor phase to the deposition chamber. Each of the two timing diagrams 40 and 42 in the example in FIG. 4 illustrate pulse delivery of micro-moles quantities to the heater of a separate type of lubricant introduced to enable mixed-lube processing. The providing of only pre-determined measured micro-moles of sufficient quantities of lubricant to the heater enables conservation of costly lubricant in process. In addition, heating only pre-determined sufficient quantities from the reservoir, instead of the entire quantity in the reservoir, minimizes the thermal decomposition which causes contamination and fractionation of the lubricant. Heating only sufficient pre-determined quantities of liquid, according to an embodiment of the present invention, also eliminates the need for a higher reservoir temperature to keep relatively constant vapor pressure in known systems that continuously heat all the liquid in the reservoir; the continuous heating causing progressive increase of molecular weight for the remaining lubricant.

Moreover, as exemplified in FIG. 4, at time tᵢ, when the disk is removed from the chamber, no liquid is delivered to the evaporator, so there is no unnecessary heating of liquid and no deleterious condensation of vapor on the chamber walls when no disk is present.

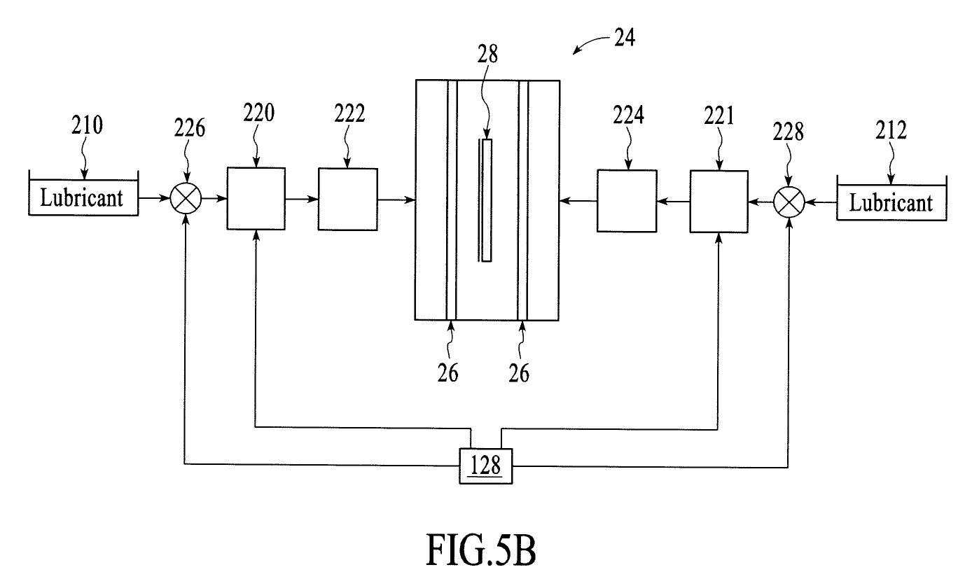

FIG. 5A is a diagram illustrating isolation of the deposition chamber vacuum from the reservoir of lubricant liquid for enabling replenishment of lubricant liquid without disrupting vacuum operations, according to an embodiment of the present invention. FIG. 5 illustrates the flow from each of two lubricant liquid reservoirs 210, 212 to the vacuum deposition chamber 24 for each of two sides of the disk 28. The lubricant is illustrated schematically in each reservoir 210, 212. The flow path between each reservoir 210, 212 and the deposition chamber 24 includes a heater 222, 224, also referred to as vaporizer, and a valve 226, 228. Lubricant vapor flows from the heater 226, 228 to the corresponding valve 226, 228. The vapor is delivered to the deposition chamber 24 in a pulse-mode through each valve 226, 228, according to the signals from the controller 120. Each valve 226, 228 may be a mechanical valve, however, other suitable valves or controllers for providing pulsed delivery of vapor may be used. The apparatus and mode of lubricant delivery in the embodiment shown in FIG. 5A provides isolation of the vacuum of the deposition chamber 24 from each reservoir 210, 212 of lubricant liquid so as to enable replenishing of the lubricant liquid in each reservoir 210, 212 without disruption of vacuum operations, i.e., enable non-intrusive lubricant refill. The isolation obviates the need to vent the deposition chamber vacuum to refill the reservoir upon depletion of the lubricant in the reservoir, the venting causing machine down time and other maintenance inconveniences in known systems.

FIG. 5B illustrates an arrangement similar to FIG. 5A, except that the valves 226, 228, are provided between the reservoirs 210, 212, and heaters 222, 224, respectively. In this embodiment, a controller 128 controls the operation of the valves 226 and 228; however, this is not a requirement. Rather, in the embodiments of FIGS. 5A and/or 5B mechanical valves may be used and may be operated manually when the system needs to be isolated from the reservoirs. The pulse delivery feature of the invention may also be incorporated in the embodiments of FIGS. 5A and 5B. As illustrated in FIG. 5B, controller 128 also activates mass flow controllers 220 and 226, so that liquid is delivered to heaters 222 and 224 in a controlled pulsed fashion. In FIG. 5A, on the other hand, the controller 120, e.g., mass flow controller, is inserted between the reservoir and the heater (similar to the embodiment of FIG. 3b), so that when valves 226 and 228 are closed, the entire liquid delivery system is isolated from the evaporation chamber 24, so that the system may be services without having to break vacuum in chamber 24.

The various aspects described above may be combined within the spirit of the invention. While there has been described and illustrated a specific embodiment of the invention, it will be clear that variations in the details of the embodiment specifically illustrated and described may be made without departing from the true spirit and scope of the invention as defined in the appended claims.

What is claimed is:

1. An apparatus for applying lubricant coatings to magnetic disks, the apparatus comprising:
a reservoir for a liquid;
a heater for heating at least a portion of the liquid to a vapor;
a controller to control flow of the liquid to the heater such that only a selectable amount of the liquid from the reservoir flows to the heater at a time, the heater heating the pre-determined amount to the vapor; and
an apertured diffuser situated in the flow path of the vapor.

2. The apparatus of claim 1, further comprising:
a second reservoir for a second liquid;
a second heater for heating at least a portion of the second liquid to a second vapor; the second vapor to flow to the disk through the apertured diffuser.

3. The apparatus of claim 2; wherein the first vapor flowing to the apertured diffuser is at a first partial pressure and the second vapor flowing to the apertured diffuser is at a second, different partial pressure.

4. The apparatus of claim 1, wherein the selectable amount of liquid that flows to the heater is a molar quantity of less than 10 p moles.

5. The apparatus of claim 1, wherein the controller comprises a mass flow controller which provides a pulsed delivery of the selectable amount of liquid to the heater.

6. The apparatus of claim 1, further comprising a monitor for determining quantity of vapor condensed on the disk.

7. The apparatus of claim 6, wherein the quantity of vapor flowing to the apertured diffuser is measured, and the measured quantity is correlated with the quantity of lubricant vapor condensed on the disk.

8. The apparatus of claim 7, wherein a rate of deposition of the lubricant on the disk is constantly measured and is controlled through a feedback loop as a function of the correlation.

9. The apparatus of claim 8, wherein the rate of deposition is controlled through a feedback controller so as to provide closed-loop control of lubricant thickness.

10. The apparatus of claim 9 wherein the feedback controller controls the amount of heat applied by the heater to the liquid as a function of the correlation.

11. The apparatus of claim 1, further comprising a valve in a flow path between the reservoir and the apertured diffuser, providing isolation of at least the reservoir when positioned in the off position.

12. The apparatus of claim 5, wherein the controller controls at least one of the pulse width and duty cycle of the mass flow controller.

13. The apparatus of claim 6, wherein the monitor includes at least one quartz crystal microbalance (QCM) included in a gauge, wherein the build-up of lubricant thickness on the QCM's crystal is proportional to the amount of lubricant that is deposited on the disk.

14. A method for applying lubricant coatings to a disk, the method comprising:
loading a disk on a holder in a vacuum chamber;
drawing a selectable amount of liquid from a reservoir;
applying vaporizing heat to the selectable amount of liquid to form a vapor; and
supplying the vapor to the disk.

15. The method of claim 14, further including transferring the measured selectable amount of liquid from the reservoir prior to the application of vaporizing heat.

16. The method of claim 14, further including:
measuring a pre-determined amount of a second, different liquid;
applying vaporizing heat to the pre-determined amount of the second liquid to form a second vapor; and
supplying the second vapor to the disk via a flow path that includes an apertured diffuser.

17. The method of claim 14, further comprising:
monitoring the quantity of vapor condensed on the disk.

18. The method of claim 17, further comprising measuring the quantity of vapor flowing to the apertured diffuser, and correlating the measured quantity with the quantity of lubricant vapor condensed on the disk.

19. The method of claim 18, further comprising measuring a rate of deposition of the lubricant on the disk and controlling the rate of deposition through a feedback loop as a function of the correlation.

20. The method of claim 19, wherein controlling the rate of deposition includes controlling the amount of heat applied to the liquid as a function of the correlation.

21. The method of claim 14, further comprising repeatedly delivering the selectable quantity of the vapor in a pulsed fashion, and controlling at least one of the selectable amount and the time between each successive pulse delivery.

22. The method of claim 19, further comprising repeatedly delivering the selectable quantity of the vapor in a pulsed fashion, and wherein controlling the rate of deposition comprises controlling at least one of the selectable amount and the time between each successive pulse delivery.
